(19) United States
(12) Patent Application Publication
(10) Pub. No.: US 2022/0336314 A1
(43) Pub. Date: Oct. 20, 2022

(54) CHIP MODULE WITH HEAT DISSIPATION DEVICE AND MANUFACTURING METHOD THEREOF

(71) Applicant: SMArim Global Corp., Taipei City (TW)

(72) Inventor: TIEN-LAI WANG, Taipei City (TW)

(21) Appl. No.: 17/372,573

(22) Filed: Jul. 12, 2021

(30) Foreign Application Priority Data
Apr. 15, 2021 (TW) 110113491

(51) Int. Cl. H01L 23/367; H01L 23/00; H01L 21/48

(52) U.S. Cl. CPC H01L 23/367; H01L 24/16; H01L 24/81; H01L 21/4882; H01L 24/09; H01L 2224/81207; H01L 2224/81815; H01L 2224/16258; H01L 2224/16155; H01L 2224/09519; H01L 2224/0913

(57) ABSTRACT

A chip module with heat dissipation device includes device includes a chip unit, a heat dissipation body and a plurality of metal connecting elements. The heat dissipation body is disposed on the chip unit. The plurality of metal connecting elements formed by ultrasonic bonding are disposed between the chip unit and the heat dissipation body to connect the chip unit to the heat dissipation body.

### CROSS REFERENCE TO RELATED APPLICATION

This application claims the benefits of Taiwan application Serial No. 110113491, filed on Apr. 15, 2021, the disclosures of which are incorporated by references herein in its entirety.

### TECHNICAL FIELD

The present disclosure relates in general to a chip module with heat dissipation device, and also to a manufacturing method of the chip module.

### BACKGROUND

The thermal grease, also called as a thermal paste, is a paste-like substance with good thermal conductivity (but mostly non-conductive). Generally, the thermal grease is used on the interface between a radiator and a connected heat source (such as an electronic part that may not work well or have a reduced life due to heat). The main function of the thermal grease is to replace the air or to fill the gap at the interface for improving the conductivity, i.e., for promoting the heat transfer. In the art, the thermal grease is one of thermal interface materials.

The thermal grease is different from a heat conduction glue. Although the thermal grease itself has a little viscosity, yet it still cannot fix the radiator and the heat source firmly together. Thus, other mechanical fixing components such as screws, are needed to fix the heat sink and the heat source as a unique piece. In addition, while being applied with a pressure onto the interface between the radiator and the heat source, the thermal grease should be fully distributed in a part of the heat source where exists no direct contact with the radiator. Nevertheless, in order to be applied on personal computers (PC), the thermal grease is usually packaged in a form of syringe.

In the art, the thermal grease would include a liquid polymer matrix and a large number of thermally but not electrically conductive fillers. The liquid polymer matrix can be a typical matrix material such as silicone, polyurethane, acrylate polymer, hot melt adhesive, or pressure sensitive adhesive. The filler can be aluminum oxide, boron nitride, zinc oxide, aluminum nitride or the like. The filler may share 70-80 wt% of the thermal grease, such that the thermal conductivity can be ensured. For example, in a silver-containing thermal grease, the thermal conductivity may be as high as 3 to 8 W/(m·K) or even higher. However, the metal-containing thermal grease would be electrically conductive and mostly capacitive. If such a metal-containing thermal grease is overflowed to touch the circuit, malfunction or even short-circuit damage in the circuit would be inevitable.

Nevertheless, the thermal resistance, a property related to heat, is referred to the ability of an object to resist heat transfer in the presence of a temperature difference. Generally, the higher the thermal conductivity of the object is, the lower the thermal resistance would be. Most of electronic components would generate heat during operation. If an instant temperature of a working electronic component goes too high, then the electronic component may face a risk of fail. Definitely, an overheated component shall be cooled down anyway. In this circumstance, a heat dissipation device is usually introduced to dissipate the heat generated by the working electronic component. In applying the heat dissipation device, the absolute thermal resistance thereof shall be properly arranged, so that the heat generated by the electronic component can be well dissipated to avoid possible failure of the electronic component due to excessive heat accumulation.

### SUMMARY

In one embodiment of this disclosure, a chip module with heat dissipation device includes a chip unit, a heat dissipation body and a plurality of metal connecting elements. The heat dissipation body is disposed on the chip unit. The plurality of metal connecting elements are disposed between the chip unit and the heat dissipation body to connect the chip unit to the heat dissipation body.

In another embodiment of this disclosure, a manufacturing method of a chip module with heat dissipation device includes the steps of: providing a chip unit having a plurality of first metal pads; forming a plurality of second metal pads on a heat dissipation body; and, applying a bonding process to connect individually the plurality of first metal pads and the plurality of second metal pads to form a plurality of metal connecting elements.

The thermosonic die bonding is a low-temperature, clean and dry package die bonding technology that provides ultrasonic vibrations to bond two metals together. Practically, the thermosonic die bonding is specifically applied to gold-to-gold bonding. Since the operation temperature of a traditional hot press bonding is generally higher than 270° C. , thus, if applied to the gold-to-gold bonding, such a high operation temperature may easily damage the substrate or some sensitive chips. However, the thermosonic die bonding can greatly reduce the bonding temperature to less than 150° C., and does not require a flux or a post-soldering cleaning procedure.

If the surface material of a die pad is gold, a thermosonic process is usually applied to connect the gold and the nickel. Since the thermosonic process can reduce the operation temperature, thus possible formation of oxides on the metal surface due to the high temperature, which will lead to ill crystallization at the weld, can be avoided of the operation and cause the common gold failure.

In this disclosure, the metal pads, the metal protrusions and the thermosonic die bonding are adopted to replace the traditional use of the thermal grease or other adhesives to connect the chip unit and the heat dissipation body. Thereupon, the problem of high thermal resistance caused by the thermal grease can be resolved, thus the yield in internal electric connection of the electronic device can be raised, and the service life thereof can be extended.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic view of an embodiment of the chip module with heat dissipation device in accordance with this disclosure;

FIG. 2 demonstrates schematically a first stage of an embodiment of the manufacturing method of chip module with heat dissipation device in accordance with this disclosure;

FIG. 3 demonstrates schematically a second stage of an embodiment of the manufacturing method of chip module with heat dissipation device in accordance with this disclosure;

FIG. 4 demonstrates schematically a third stage of an embodiment of the manufacturing method of chip module with heat dissipation device in accordance with this disclosure; and

FIG. 5 is a schematic view of another embodiment of the chip module with heat dissipation device in accordance with this disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In the following description, embodiments of the chip module with heat dissipation device and the manufacturing method thereof in accordance with this disclosure will be elucidated by referring to related drawings. In these drawings, for the sake of clarity and convenience to explain the embodiments, sizes or aspects of components in the drawings may be exaggerated or reduced. In addition, in the following description and/or claims of this patent application, when an element is described to “be connected with” or “be coupled with” another element, the element can be directly or indirectly connected or coupled to the other element. However, if an element is “directly connected” or “directly coupled” to another element, it implies that no intervening element exists between the element and the connected element. In particular, the aforesaid element is directed to a component or a layer. To facilitate understanding, the same elements in the following embodiments are illustrated with the same symbols.

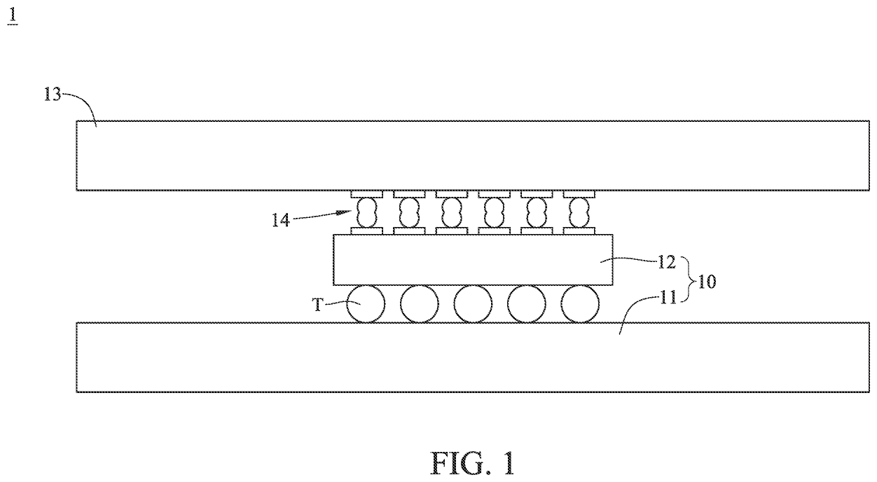

Referring to FIG. 1, an embodiment of the chip module with heat dissipation device in accordance with this disclosure is schematically shown in a side view. In this embodiment, the chip module with heat dissipation device 1 includes a chip unit 10, a heat dissipation body 13 and a plurality of metal connecting elements 14.

The chip unit 10 can be a chip package 12 disposed above a substrate 11 and connected with the substrate 11 via a plurality of solder balls T. In one exemplary example, the substrate 11 can be a PCB or the like element. The chip package 12 can be any of existing chip packages. The chip unit 10 includes the chip package 12 and the substrate 11 provided to dispose thereon the chip package 12. The connection in between can be, but not limited to, an adhesive means, a solder means or a mechanical engagement.

The heat dissipation body 13, disposed on the chip unit 10, can be, but not limited to, a heat-dissipation plate, heat-dissipation fins or any type of heat sinks.

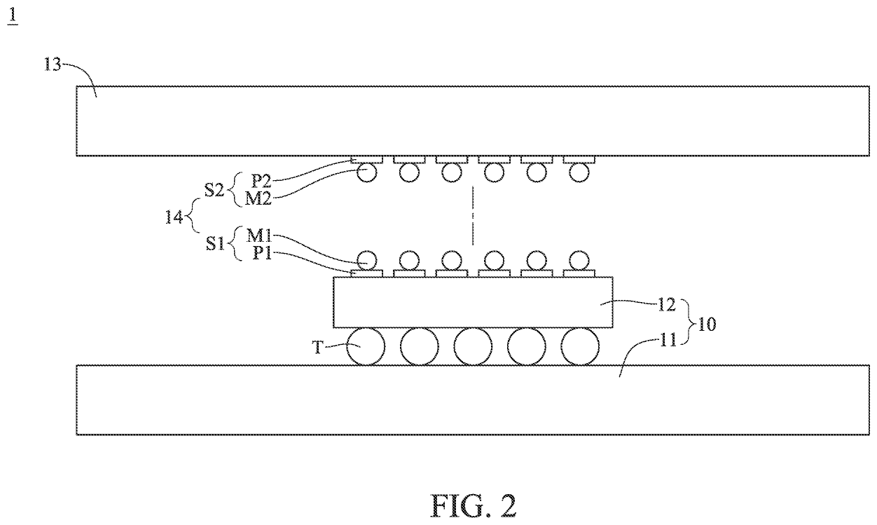

The plurality of metal connecting elements 14, arranged between the chip unit 10 and the heat dissipation body 13, are applied to connect the chip unit 10 and the heat dissipation body 13. Referring to FIG. 2, each of the metal connecting elements 14 includes a first metal pad P1, a first metal protrusion M1, a second metal pad P2 and a second metal protrusion M2. A plurality of the first metal pads P1 and a plurality of the first metal protrusions M1 are disposed on the chip unit 10, while a plurality of the second metal pads P2 and a plurality of the second metal protrusions M2 are disposed on the heat dissipation body 13 on a surface thereof facing the chip unit 10. Each pair of the first metal protrusions M1 and the corresponding second metal protrusion M2 is disposed between the first metal pad P1 and the second metal pad P2. In this embodiment, each of the plurality of the first metal protrusions M1 or each of the plurality of the second metal protrusions M2 can be, but not limited to be, made of gold (Au); while each of the plurality of the first metal pads P1 or each of the plurality of the second metal pads P2 can be, but not limited to be, made of nickel (Ni). In another embodiment, the first metal pad P1, the second metal pad P2, the first metal protrusion M1 or the second metal protrusion M2 can be made of any relevant material according to practical demands.

The plurality of the first metal protrusions M1 and the plurality of the second metal protrusions M2 are connected one-to-one by a bonding process to for the plurality of the metal connecting elements 14. Upon such an arrangement, the chip unit 10 and the heat dissipation body 13 can connect to each other through the plurality of the metal connecting elements 14. In this embodiment, the bonding process can be a thermosonic die bonding process.

In this embodiment, the plurality of the first metal pads P1 and the plurality of the corresponding first metal protrusions M1 are arranged in advance on the chip unit 10, while the plurality of the second metal pads P2 and the plurality of the corresponding second metal protrusions M2 are arranged in advance on the heat dissipation body 13. By applying the thermosonic bonding process, the plurality of the first metal protrusions M1 can be connected with the plurality of the corresponding second metal protrusions M2 so as to form the plurality of the metal connecting elements E, without any interfacing solvent, adhesive or other auxiliary chemical.

Importantly, according to this disclosure, since neither the thermal grease nor any adhesive is applied to couple the chip unit 10 and the heat dissipation body 13, thus the aforesaid concern in high thermal resistance caused by the thermal grease can be removed.

In addition, beside the advantage in waiving the high-resistance problem caused by the thermal grease, the yield in electrically connecting electronic elements can be further improved, and the service life of the electronic device can be substantially extended.

In another embodiment, the plurality of the metal connecting elements 14 can adopt a plurality of solder balls through a reflow process.

According to this disclosure, one embodiment of the manufacturing method of the chip module with heat dissipation device includes the following steps of: providing a chip unit having a plurality of first sub-metal connecting elements; forming a plurality of second sub-metal connecting elements on a heat dissipation body; and applying a bonding process to connect individually and correspondingly the plurality of first sub-metal connecting elements to the plurality of second sub-metal connecting elements so as to form a plurality of metal connecting elements.

Referring to FIGS. 2-4, three stages of this embodiment of the manufacturing method of chip module with heat dissipation device are demonstrated schematically. As shown in FIG. 2, the plurality of first metal pads P1 are formed on the chip unit 10, and then the plurality of first metal protrusions M1 are formed individually on the corresponding first metal pads P1, such that the plurality of first sub-metal connecting elements S1 can be formed. Similarly, the plurality of second metal pads P2 are formed on the heat dissipation body 13, and then the plurality of second metal protrusions M2 are formed individually on the corresponding second metal pads P2, such that the plurality of second sub-metal connecting elements S2 can be formed. In other words, the plurality of metal connecting elements 14 are arranged in advance to be disposed on the chip unit 10 or/and the heat dissipation body 13.

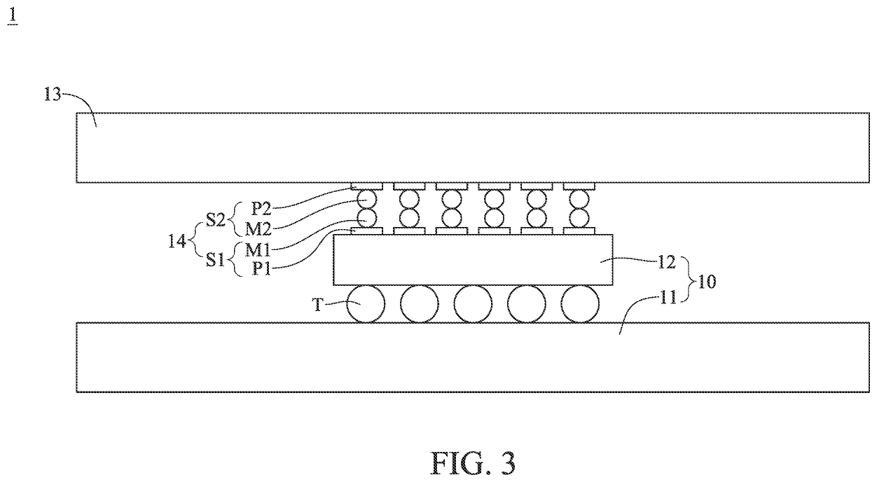

As shown in FIG. 3, the plurality of first sub-metal connecting elements S1 are sent to contact individually and correspondingly the plurality of second sub-metal connecting elements S2, such that a thermosonic bonding process can then be performed.

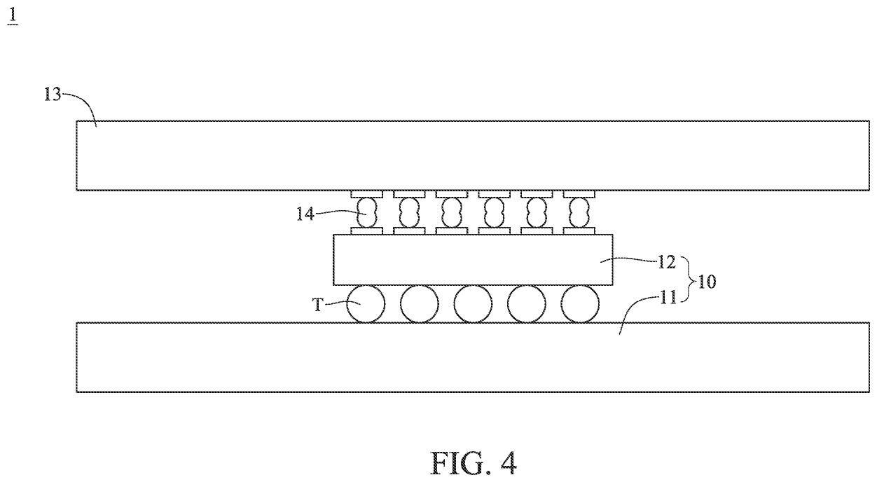

As shown in FIG. 4, in the final stage, the plurality of first sub-metal connecting elements S1 and the plurality of second sub-metal connecting elements S2 are correspondingly connected to form the plurality of metal connecting elements 14.

In a further embodiment of this disclosure, the plurality of metal connecting elements 14 may exclude the second metal protrusions M2. Then, while in performing the ultrasonic bonding, the first metal protrusions are melted to directly connect the chip unit 10 to the heat dissipation body 13. In detail, the arrangement of the plurality of metal connecting elements is not specifically limited to any particular pattern, and is not limited to be prepared on the chip unit 10 or the heat dissipation body 13. In this embodiment, as long as the plurality of metal connecting elements is arranged in advance to be disposed on one of the chip unit 10 and the heat dissipation body 13, the following thermosonic bonding process can be then performed immediately.

Certainly, the aforesaid description upon the chip module with heat dissipation device of this disclosure is for the associated embodiments only. According to this disclosure, embodying of components and the associated relationships in between for the chip module with heat dissipation device can be varied or adjusted to meet practical needs, and this disclosure is not limited thereto.

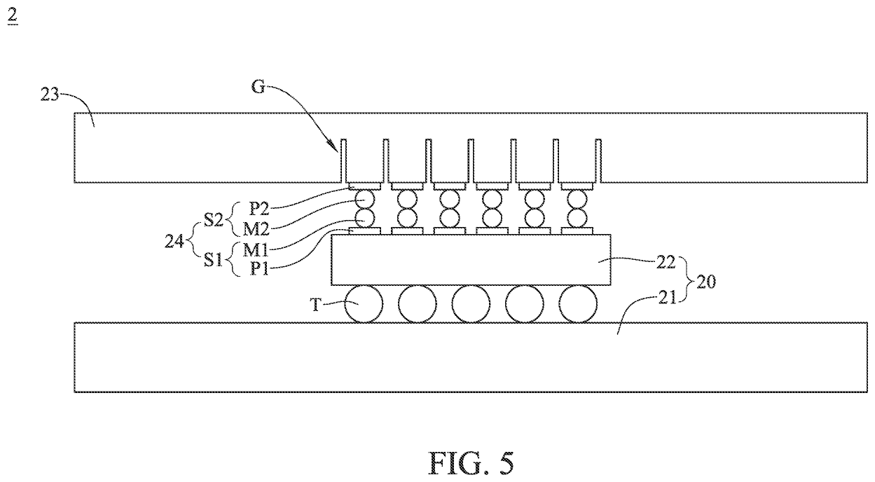

Referring to FIG. 5, another embodiment of the chip module with heat dissipation device in accordance with this disclosure is schematically shown in a side view. In this embodiment, the chip module with heat dissipation device 2 includes a chip unit 20, a heat dissipation body 23 and a plurality of metal connecting elements 24.

In this embodiment, any element similar to the element of the aforesaid embodiment would be assigned by the same sign, and details thereabout would be omitted herein. The difference between this and the aforesaid embodiments is that, in this embodiment, the heat dissipation body 23 further includes at least one groove G. Preferably, the groove G is disposed between two neighboring second metal pads P2. By providing the at least one groove G, possible location shift between the chip unit 20 and the heat dissipation body 23 caused by different expansion coefficients can be substantially reduced. In other words, due to different materials, and thus different thermal coefficients, to the chip unit 20 and the heat dissipation body 23, while the electronic device of this disclosure is operated in a high temperature area, the inclusion of the groove G would relieve internal stress and strain formed during the boding process between the chip unit 20 and the heat dissipation body 23. Thereupon, unexpected fractures or cracks at the metal connecting elements 24 can be significantly reduced. As such, the yield in internal electric connection of the electronic device can be improved, and also the service life thereof can be substantially extended.

The second metal pads P2 of the chip unit 20 are arranged into an X×Y matrix formation with X rows and Y columns, in which X is an even number. The groove G would be formed as a linear aperture located between the (X/2)^{th} row and the (X/2+1)^{th} row of the second metal pads P2. For example, in a 6×8 matrix formation of the second metal pads P2, a groove G exists between the third and the fourth rows, or between the fourth and the fifth rows. In other words, if the second metal pads P2 are disposed on a second surface of the chip unit 20, then the groove G would divide the second metal pads P2 into two halves on the second surface, preferably in a mirror symmetry. Upon such an arrangement, the aforesaid ill thermal effects upon the electric device can be substantially overcome, and possible fractures of cracks at the metal connecting elements 24 can be avoided.

In another exemplary example, the second metal pads P2 of the chip unit 20 are arranged into an X×Y matrix formation with X rows and Y columns, in which both X and Y are even numbers. The groove G would extend to form a square and thus to divide the second metal pads P2 into a first heat conduction zone and a second heat conduction zone. For example, in a 6×8 matrix formation of the second metal pads P2, the groove G is extended between the second and the third rows, between the fourth and the fifth rows, between the second and the third columns, and between the sixth and the seventh columns, such that the square can be defined. In other words, the second metal pads P2 on the chip unit 20 would be divided by the groove G into a central portion and a surrounding portion; i.e., a first heat conduction zone and a second heat conduction zone, respectively. Upon such an arrangement, the aforesaid ill thermal effects upon the electric device can be substantially overcome, and possible fractures of cracks at the metal connecting elements 24 can be avoided.

In summary, according to the aforesaid embodiments of this disclosure, the chip module with heat dissipation device can adopt the bonding process to form a plurality of metal connecting elements to electrically connect the chip unit and the heat dissipation body, such that no thermal grease is required, and the performance of heat dissipation can be greatly improved.

In addition, according to the aforesaid embodiments of this disclosure, the chip module with heat dissipation device can adopt the bonding process to form a plurality of metal connecting elements to electrically connect the chip unit and the heat dissipation body, such that no thermal grease is required, thus the yield in internal electric connection of the electronic device can be raised, and the service life thereof can be extended.

Further, according to the aforesaid embodiments of this disclosure, the heat dissipation body of the chip module with heat dissipation device includes at least one groove to be located among the plurality of second metal pads, such that cracks or fractures at the metal connecting elements caused by different thermal expansion coefficients to the chip unit and the heat dissipation body can be substantially avoided.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A chip module with heat dissipation device, comprising:
a chip unit;
a heat dissipation body, disposed on the chip unit; and
a plurality of metal connecting elements, disposed between the chip unit and the heat dissipation body to connect the chip unit to the heat dissipation body.

2. The chip module with heat dissipation device of claim 1, wherein each of the plurality of metal connecting elements includes a first metal pad, a first metal protrusion, a second metal pad and a second metal protrusion, the first metal protrusion is connected with the second metal protrusion, and the first metal protrusion is located between the first metal pad and the second metal pad.

3. The chip module with heat dissipation device of claim 2, wherein a plurality of the first metal pads and a plurality of the metal protrusions are disposed on the chip unit, and a plurality of the second metal pads and a plurality of the second metal protrusions are disposed on the heat dissipation body.

4. The chip module with heat dissipation device of claim 1, wherein the plurality of metal connecting elements are formed through a thermosonic bonding process.

5. The chip module with heat dissipation device of claim 1, wherein the heat dissipation body further includes at least one groove formed on the heat dissipation body and located between two of the plurality of the second metal pads.

6. The chip module with heat dissipation device of claim 5, wherein the plurality of the second metal pads are arranged into an X×Y matrix formulation with X rows and Y columns, the X is an even number, and the at least one groove is formed as a linear aperture located between the (X/2)^{th} row and the (X/2+1)^{th} row of the plurality of the second metal pads.

7. The chip module with heat dissipation device of claim 5, wherein the plurality of the second metal pads are arranged into an X×Y matrix formation with X rows and Y columns, both the X and the Y are even numbers, and the at least one groove extends to form a square to divide the plurality of the second metal pads into a first heat conduction zone and a second heat conduction zone.

8. The chip module with heat dissipation device of claim 1, wherein the plurality of metal connecting elements are a plurality of solder balls.

9. The chip module with heat dissipation device of claim 1, wherein the plurality of metal connecting elements are formed through a reflow process.

10. A manufacturing method of a chip module with heat dissipation device, comprising the steps of:
(a) providing a chip unit having a plurality of first metal pads;
(b) forming a plurality of second metal pads on a heat dissipation body; and
(c) applying a bonding process to connect individually the plurality of first metal pads and the plurality of second metal pads to form a plurality of metal connecting elements.

11. The manufacturing method of a chip module with heat dissipation device of claim 10, further including a step of forming a groove on the heat dissipation body, the groove being disposed among the plurality of second metal pads.

12. The manufacturing method of a chip module with heat dissipation device of claim 10, wherein the plurality of second metal pads are arranged into an X×Y matrix formulation with X rows and Y columns, the X is an even number, and the groove is formed as a linear aperture located between the (X/2)^{th} row and the (X/2+1)^{th} row of the plurality of second metal pads.

13. The manufacturing method of a chip module with heat dissipation device of claim 10, wherein the plurality of second metal pads are arranged into an X×Y matrix formation with X rows and Y columns, both the X and the Y are even numbers, and the at least one groove extends to form a square to divide the plurality of the second metal pads into a first heat conduction zone and a second heat conduction zone.

14. The manufacturing method of a chip module with heat dissipation device of claim 10, wherein the bonding process is a thermosonic bonding process.

15. The manufacturing method of a chip module with heat dissipation device of claim 10, wherein the plurality of metal connecting elements are formed as a plurality of solder balls.

16. The manufacturing method of a chip module with heat dissipation device of claim 10, wherein the bonding process is a reflow process.
